(19) United States
(12) Patent Application Publication
(10) Pub. No.: US 2016/0064262 A1
(43) Pub. Date: Mar. 3, 2016

(54) SEMICONDUCTOR MANUFACTURING APPARATUS, SEMICONDUCTOR MANUFACTURING SYSTEM, AND SEMICONDUCTOR MANUFACTURING METHOD

(71) Applicant: KABUSHIKI KAISHA TOSHIBA, Tokyo (JP)

(72) Inventors: Yoshihisa OOSAKI, Yokkaichi (JP); Mitsuyoshi MEGURO, Yokkaichi (JP); Shouji HONDA, Kuwana (JP); Yuuji IDE, Yokkaichi (JP); Masato KURITA, Yokkaichi (JP); Tomofumi INOUE, Yokkaichi (JP)

(21) Appl. No.: 14/656,762

(22) Filed: Mar. 13, 2015

(30) Foreign Application Priority Data
Aug. 28, 2014 (JP) 2014-174536

(51) Int. Cl. H01L 21/67; C23C 16/52; H01L 21/02; C23C 16/455; H01L 21/66; C23C 16/50; C23C 16/46

(52) U.S. Cl. CPC H01L 21/67253; C23C 16/50; C23C 16/52; C23C 16/46; C23C 16/45563; C23C 16/45587; H01L 22/12; H01L 21/022; H01L 21/02274

(57) ABSTRACT

The semiconductor manufacturing apparatus includes a film forming part and a control part. The film forming part forms a stacked film on a semiconductor substrate. The stacked film has a lower layer and an upper layer on the lower layer. The control part controls the film forming part. The control part controls the film forming part to form the upper layer film in which an inclination of a film thickness is inverted with respect to that of the lower layer film.

### CROSS REFERENCE TO RELATED APPLICATIONS

This application is based upon and claims the benefit of priority from the prior Japanese Patent Application No. 2014-174536, filed on Aug. 28, 2014, the entire contents of which are incorporated herein by reference.

### FIELD

Embodiments of the present invention relate to a semiconductor manufacturing apparatus, a semiconductor manufacturing system, and a semiconductor manufacturing method.

### BACKGROUND

When a semiconductor device having a stacked film is to be manufactured, a stacked-film forming process is performed in which a single layer film is repeatedly formed.

In the stacked-film forming process, it is important to flatten the top surface of the stacked film to facilitate processing (for example, lithography) after the stacked-film forming process.

However, in a film forming technique, even in a single-layer-film forming process, it is difficult to secure uniformity (hereinafter, also “in-plane uniformity”) of a film thickness in a wafer plane.

Accordingly, in the stacked-film forming process in which the single-layer-film forming process is repeated, it is naturally difficult to flatten the top surface of the stacked film. The reason is that flatness of an upper layer film of the stacked film is affected by poorness in flatness of a lower layer film in addition to a non-uniform film thickness of the upper layer film itself and thus is deteriorated more than that of the lower layer film. As a result, in the stacked-film forming process, it is more difficult to flatten the top surface of the stacked film than in the single-layer-film forming process.

### BRIEF DESCRIPTION OF THE DRAWINGS

FIG. 1 is a schematic diagram showing an example of a configuration of a semiconductor manufacturing system 1 according to an embodiment;

FIG. 2 is a cross-sectional view showing an example of a configuration of a stacked film 20 formed by the semiconductor manufacturing system 1 shown in FIG. 1;

FIGS. 3A to 3C show film forming parameter-associated data of the semiconductor manufacturing system 1 shown in FIG. 1;

FIGS. 4A and 4B are graphs showing basic data of the semiconductor manufacturing system 1 shown in FIG. 1; and

FIG. 5 is a flowchart showing a film forming process of the semiconductor manufacturing system 1 shown in FIG. 1.

### DETAILED DESCRIPTION

A semiconductor manufacturing apparatus according to an embodiment comprises a film forming part and a control part. The film forming part forms a stacked film on a semiconductor substrate. The stacked film has a lower layer and an upper layer on the lower layer. The control part controls the film forming part. The control part controls the film forming part to form the upper layer film in which an inclination of a film thickness is inverted with respect to that of the lower layer film.

Embodiments will now be explained with reference to the accompanying drawings. The present invention is not limited to the embodiments.

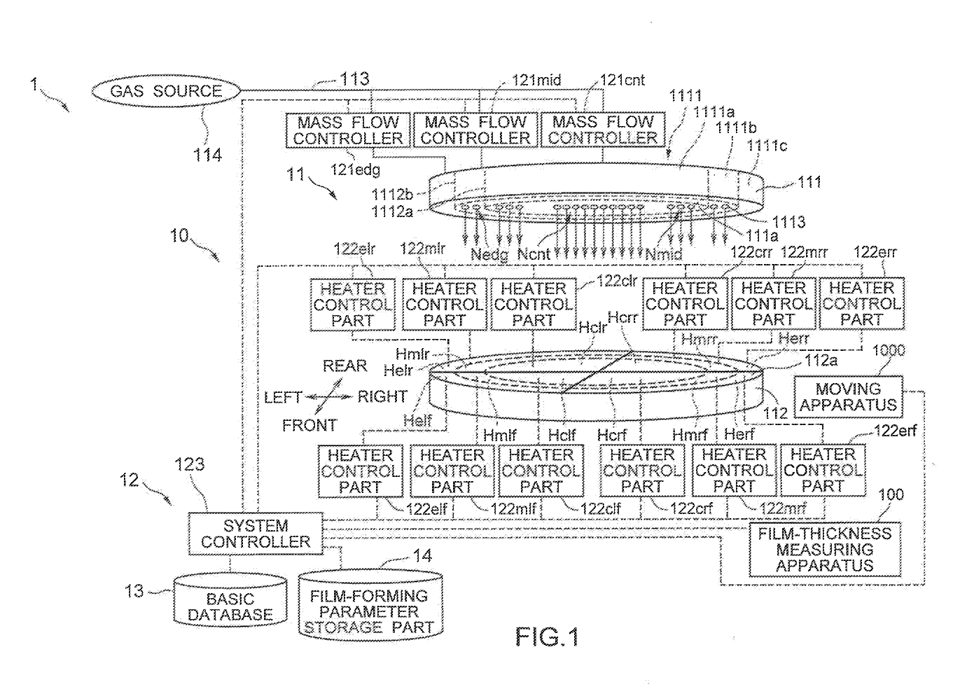

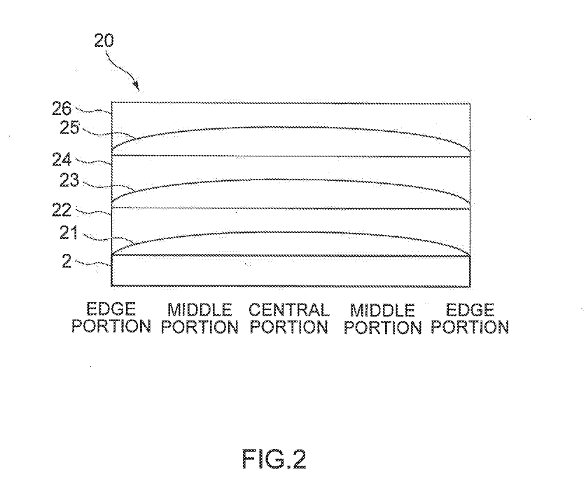

FIG. 1 is a schematic diagram showing an example of a configuration of a semiconductor manufacturing system 1 according to an embodiment. FIG. 2 is a cross-sectional view showing an example of a stacked film 20 formed by the semiconductor manufacturing system 1 shown in FIG. 1. The semiconductor manufacturing system 1 includes a semiconductor manufacturing apparatus 10, a film-thickness measuring apparatus 100, and a moving apparatus 1000.

The semiconductor manufacturing apparatus 10 includes a film forming part 11, a control part 12, a basic database 13, and a film-forming parameter storage part 14. As shown in FIG. 2, the film forming part 11 forms the stacked film 20 by stacking a plurality of layers of films 21 to 26 on a semiconductor substrate 2. The control part 12 controls the film forming part 11. The basic database 13 has basic data indicating a correspondence relationship between film thicknesses and film forming parameters stored therein. The film-forming parameter storage part 14 has data associated with film forming parameters (hereinafter, “film forming parameter-associated data”, which is described later) stored therein.

### (Film Forming Part 11)

The film forming part 11 is, for example, a plasma CVD device and has a showerhead electrode (cathode) 111 and a susceptor (anode) 112 facing each other in the vertical direction within a vacuum chamber (not shown). A bottom surface 111a of the showerhead electrode 111 and a top surface 112a of the susceptor 112 are formed substantially concentrically. Between the electrodes 111 and 112, plasma is generated by application of high frequency waves from a power supply (not shown). The top surface 112a of the susceptor 112 is a stage on which a discoid semiconductor substrate 2 (wafer) is mounted and the semiconductor substrate 2 is mounted on the top surface 112a concentrically with the top surface 112a.

The showerhead electrode 111 internally has a gas chamber 1111 and a film forming gas is supplied from a gas source 114 through a pipe 113 to the gas chamber 1111. The gas chamber 1111 is divided into three, that is, a central compartment 1111a, a middle compartment 1111b, and an edge compartment 1111c by two concentric cylindrical partition walls 1112a and 1112b having diameters different from each other. The pipe 113 is branched into three portions to supply the film forming gas to the compartments 1111a to 1111c.

In the bottom surface 111a of the showerhead electrode 111, a plurality of through-holes 1113 are formed to be communicated with the gas chamber 1111. The through-holes 1113 are arranged to correspond to an arrangement of the compartments 1111a to 1111c and are divided into three zones of a central portion, a middle portion, and an edge portion. Ones of the through-holes 1113 arranged in one of the three zones form a gas nozzle N (cnt, mid, or edg) of the corresponding zone to which the through-holes 1113 belong.

The gas nozzle Ncnt of the central portion injects the film forming gas supplied to the central compartment 1111a toward a central portion (see FIG. 2) of the semiconductor substrate 2 mounted on the susceptor 112. The gas nozzle Nmid of the middle portion injects the film forming gas supplied to the middle compartment 1111b toward a middle portion (see FIG. 2) of the semiconductor substrate 2. The gas nozzle Nedg of the edge portion injects the film forming gas supplied to the edge compartment 1111c toward an edge portion (see FIG. 2) of the semiconductor substrate 2. The injected film forming gas is decomposed by the plasma generated between the electrodes 111 and 112 and reaches a surface of the semiconductor substrate 2 as a film forming seed. The above process enables a film formation on the semiconductor substrate 2 to be performed. For example, by repeating the formation of a single layer film while the film forming gas is changed, the stacked film 20 is obtained in which films having different materials are stacked.

To the three gas nozzles N, flow rates of the film forming gas can be set individually by three mass flow controllers 121 (described later), respectively. The film thickness can be thus adjusted individually for zones of the semiconductor substrate 2 corresponding to the nozzles N, respectively. The reason is that the film thickness depends on the flow rate of the film forming gas and the film thickness becomes thicker as the flow rate in the zone is higher. By individually adjusting the film thicknesses for the zones of the semiconductor substrate 2 corresponding to the nozzles N in this way, inclinations (hereinafter, also “in-plane inclinations”) of the film thicknesses of the layers of the stacked film 20 can be adjusted. It can be said that the in-plane inclination is an inclination of the film thickness of each of the layers of the stacked film 20 in a plane of the semiconductor substrate 2 (wafer) (in other words, a direction parallel to the plane or a plane direction). The number of the gas nozzles is not limited to three and can be variously changed according to the division number of the gas chambers.

Twelve heaters H (clf, clr, crf, crr, mlf, mlr, mrf, mrr, elf, elr, erf, and err) are built-in in the susceptor 112 to increase a film forming rate. Each of the heaters H is, for example, made of a carbon plate that produces heat with energization. The heaters H are arranged to correspond to a total of twelve division zones obtained by concentrically dividing the top surface 112a of the susceptor 112 into three portions and also dividing the top surface 112a into four portions of front, rear, right, and left portions.

The heater Hclf heats a portion of the semiconductor substrate 2 that is located in a left front zone of the central portion in the top surface 112a of the susceptor 112. The heater Hclr heats a portion of the semiconductor substrate 2 that is located in a left rear zone of the central portion. The heater Hcrf heats a portion of the semiconductor substrate 2 that is located in a right front zone of the central portion. The heater Hcrr heats a portion of the semiconductor substrate 2 that is located in a right rear zone of the central portion. The heater Hmlf heats a portion of the semiconductor substrate 2 that is located in a left front zone of the middle portion. The heater Hmlr heats a portion of the semiconductor substrate 2 that is located in a left rear zone of the middle portion. The heater Hmrf heats a portion of the semiconductor substrate 2 that is located in a right front zone of the middle portion. The heater Hmrr heats a portion of the semiconductor substrate 2 that is located in a right rear zone of the middle portion. The heater Helf heats a portion of the semiconductor substrate 2 that is located in a left front zone of the edge portion. The heater Helr heats a portion of the semiconductor substrate 2 that is located in a left rear zone of the edge portion. The heater Herf heats a portion of the semiconductor substrate 2 that is located in a right front zone of the edge portion. The heater Herr heats a portion of the semiconductor substrate 2 that is located in a right rear zone of the edge portion.

To the twelve heaters H, heating temperatures can be individually set by twelve heater control parts 122 (described later), respectively. The film thicknesses thus can be individually adjusted for the portions of the semiconductor substrate 2 corresponding to the heaters H, respectively. The reason is that the film thickness depends on a temperature of the semiconductor substrate 2 and the film thickness becomes thicker as the temperature is higher. By individually adjusting the film thicknesses for the portions of the semiconductor substrate 2 corresponding to the heaters H, respectively, the in-plane inclinations of the layers of the stacked film 20 can be adjusted more finely together with the three gas nozzles N.

According to the present embodiment, an adjustment of the film thickness can be performed by dividing the top surface 112a of the susceptor 112 into twelve division zones depending on the number of the heaters H. The number of the heaters is not limited to twelve and can be variously changed. In the present embodiment, the number of the heaters H is more than the number of the gas nozzles N and therefore the number of the division zones depends on the number of the heaters H. However, the number of the gas nozzles N can be more than that of the heaters H and accordingly the number of the division zones can depend on the number of the gas nozzles N.

The moving apparatus 1000 can move the semiconductor substrate 2 between the film forming part 11 and the film-thickness measuring apparatus 100. The moving apparatus 1000 is, for example, a hoop automatic transfer mechanism that houses therein a wafer. In the course of the stacked-film forming process, the moving apparatus 1000 transfers the semiconductor substrate 2 to the film-thickness measuring apparatus 100 each time a single layer film is formed. The film-thickness measuring apparatus 100 measures the film thickness of an uppermost layer of the semiconductor substrate 2 transferred by the moving apparatus 1000 and notifies the control part 12 of the measurement results. These operations of the moving apparatus 1000 and the film-thickness measuring apparatus 100 are controlled by the control part 12. A relationship between the film thickness measurement and the film formation is described later.

### (Control Part 12)

The control part 12 includes the three mass flow controllers 121 (cnt, mid, and edg) corresponding to the three gas nozzles N, respectively. The control part 12 also includes the twelve heater control parts 122 (clf, clr, crf, crr, mlf, mlr, mrf, mrr, elf, elr, erf, and err) corresponding to the twelve heaters H, respectively. The control part 12 further includes a system controller 123. The system controller 123 controls the mass flow controllers 121 and the heater control parts 122 based on the measurement results of the film thickness obtained by the film-thickness measuring apparatus 100. The system controller 123 can be configured by one computer or by mutually linking a plurality of computers that manage the film forming part 11, the film-thickness measuring apparatus 100, the basic database 13, and the moving apparatus 1000, respectively.

The mass flow controllers 121 control the flow rates of the film forming gas for the corresponding gas nozzles N, respectively, under the control of the system controller 123. Based on the measurement results of the film thickness of a lower layer film by the film-thickness measuring apparatus 100, the mass flow controllers 121 control the corresponding gas nozzles N, respectively, to form an upper layer film in which the in-plane inclination is inverted with respect to that of the lower layer film.

For example, when the film thickness of a lower layer film is reduced from the central portion to the edge portion, the mass flow controllers 121 control the gas nozzles N, respectively, in such a manner that the film thickness of an upper layer film is increased from the central portion to the edge portion. In this case, the mass flow controllers 121 can minimize the flow rate of the gas nozzle Ncnt of the central portion and maximize the flow rate of the gas nozzle Nedg of the edge portion.

The heater control parts 122 control the heating temperatures for the corresponding heaters H, respectively, under the control of the system controller 123. Based on the measurement results of the film thickness of the lower layer film by the film-thickness measuring apparatus 100, the heater control parts 122 control the corresponding heaters H, respectively, to form the upper layer film in which the in-plane inclination is inverted with respect to that of the lower layer film.

For example, it is assumed that the film thickness of a lower layer film is reduced from the left front zone of the edge portion mentioned above toward the right rear zone of the edge portion, and also the film thickness thereof is increased from the right front zone of the edge portion toward the left rear zone of the edge portion. In this case, the heater control parts 122 can control the corresponding heaters H, respectively, in such a manner that the film thickness of an upper layer film is increased from the left front zone of the edge portion toward the right rear zone of the edge portion, and also the film thickness thereof is reduced from the right front zone of the edge portion toward the left rear zone of the edge portion. In this case, for example, the heater control parts 122 can maximize the temperature of the heater Herr or Herf corresponding to the right rear zone or the right front zone of the edge portion and minimize the temperature of the heater Helf or Helr corresponding to the left front zone or the left rear zone of the edge portion.

In the control of the mass flow controllers 121 and the heater control parts 122 by the system controller 123, the basic data stored in the basic database 13 and the film forming parameter-associated data stored in the film-forming parameter storage part 14 are used. Details thereof are described later.

If a stacked film is obtained by repeating a formation of a single layer film with the same in-plane inclination, flatness of the top surface of the film is reduced as more layer are stacked. For example, it is assumed an in-plane inclination in which the film thickness is reduced from the central portion of the film toward the edge portion thereof. A difference between a height of the central portion with respect to the top surface of the semiconductor substrate 2 and that of the edge portion is larger in an upper layer film than in a lower layer film (that is, the upper layer film becomes less flat).

On the other hand, in the present embodiment, the in-plane inclination of the upper layer film can be inverted with respect to that of the lower layer film and therefore the in-plane inclination of the lower layer film can be absorbed by that of the upper layer film. As a result, the top surface of each layer of the stacked film can be flattened more than in the conventional technique.

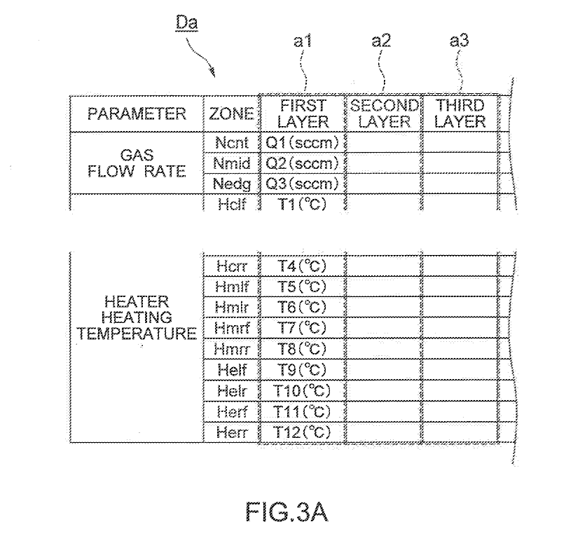

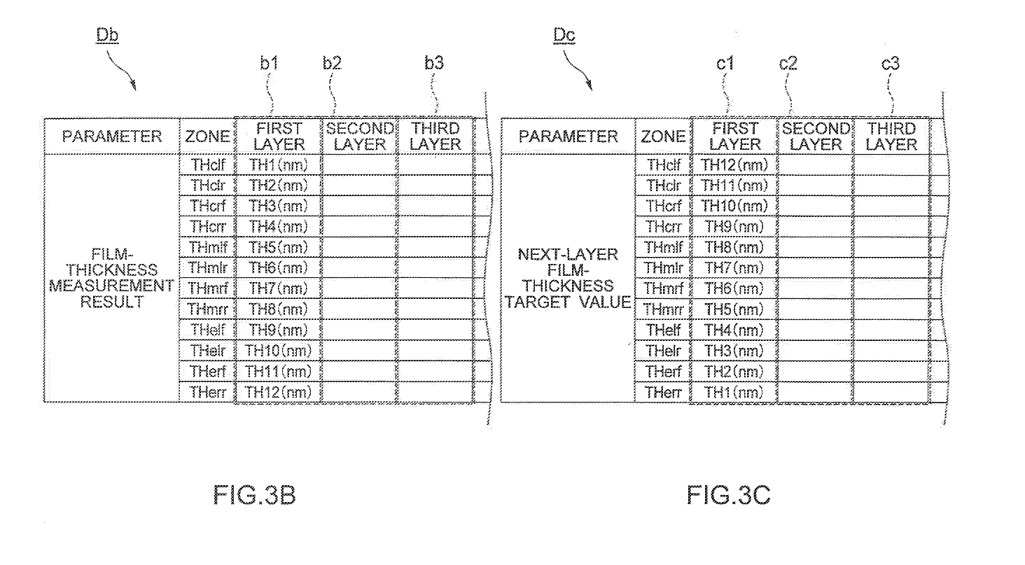

Next, a film forming process of the semiconductor manufacturing system 1 shown in FIG. 1 is explained with reference to FIGS. 3 to 5.

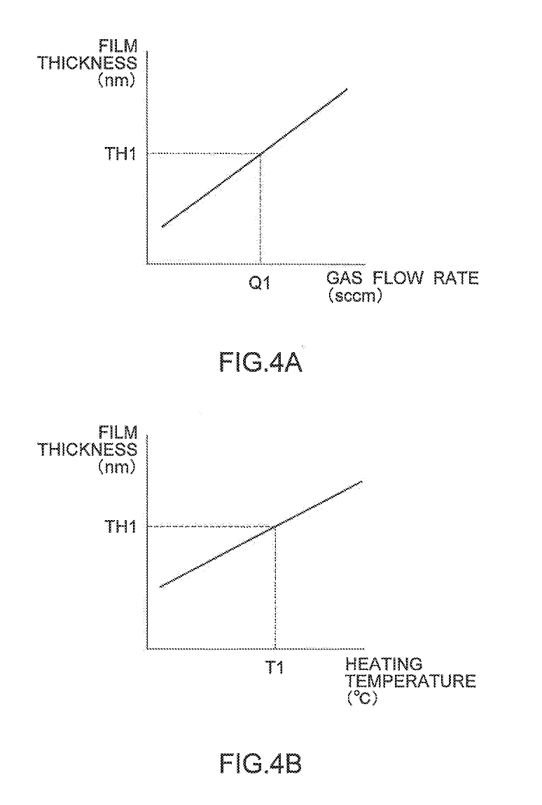

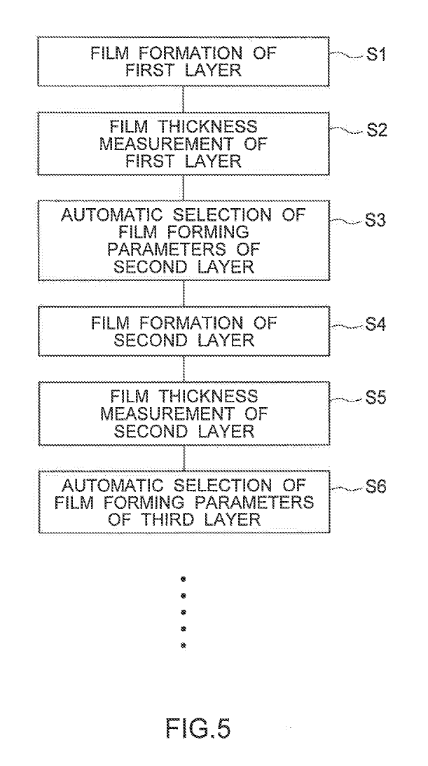

FIG. 3A shows film-forming parameter data in the film forming parameter-associated data of the semiconductor manufacturing system 1 shown in FIG. 1. FIG. 3B shows film-thickness measurement result data in the film forming parameter-associated data. FIG. 3C shows next-layer film-thickness target value data in the film forming parameter-associated data. FIG. 4A is a graph schematically showing a function between the film thickness (vertical axis) and the gas flow rate of the gas nozzle N (horizontal axis) as the basic data of the semiconductor manufacturing system 1 shown in FIG. 1. FIG. 4B is a graph schematically showing a function between the film thickness (vertical axis) and the heating temperature of the heater H (horizontal axis) as the basic data of the semiconductor manufacturing system 1 shown in FIG. 1. FIG. 5 is a flowchart showing the film forming process performed by the semiconductor manufacturing system 1 shown in FIG. 1.

### (Film Forming Parameter-Associated Data)

The film forming parameter-associated data is composed of film-forming parameter data Da of FIG. 3A, film-thickness measurement result data Db of FIG. 3B, and next-layer film-thickness target value data Dc of FIG. 3C.

The film-forming parameter data Da of FIG. 3A is a table showing the film forming parameters for layers of the stacked film 20 and includes film-forming parameter values a1 of a first layer, film-forming parameter values a2 of a second layer, film-forming parameter values a3 of a third layer, and the like. The film-forming parameter values (a1, a2, a3, . . . ,) of the respective layers indicate the gas flow rates (sccm) of the gas nozzles N for the respective zones at the time of forming films of the corresponding layers and the heating temperatures (° C.) of the heaters H for the zones. The film-forming parameter data Da can further indicate a power (W) of high frequency waves applied between the electrodes 111 and 112, a pressure (Pa) in the vacuum chamber, and the like.

The film-thickness measurement result data Db is a table indicating the film-thickness measurement results (nm) for the respective zones of the layers of the stacked film 20 obtained by the film-thickness measuring apparatus 100. The data Db includes film-thickness measurement values b1 of the first layer, film-thickness measurement values b2 of the second layer, film-thickness measurement values b3 of the third layer, and the like.

The next-layer film-thickness target value data Dc is a table indicating target values (nm) of the film thicknesses of the next layers for the respective zones of the layers of the stacked film 20. The data Dc includes next-layer film-thickness target values c1 of the first layer, next-layer film-thickness target values c2 of the second layer, next-layer film-thickness target values c3 of the third layer, and the like.

In the film forming parameter-associated data, the film-forming parameter values a1 of the first layer are set as a default in the film-forming parameter data Da. Other values of the film forming parameter-associated data are sequentially registered with progress of the stacked-film forming process. This registration can be performed by the system controller 123.

### (Basic Data)

The function of FIG. 4A represents, for example, that a gas flow rate of the gas nozzle N to obtain a film thickness TH1 (nm) is Q1 (sccm). The function of FIG. 4B represents, for example, that a heating temperature of the heater H to obtain the film thickness TH1 (nm) is T1 (° C.). According to the basic data indicating the above functions of FIGS. 4A and 4B, the gas flow rate of the gas nozzle N and the heating temperature of the heater H are uniquely calculated as film forming parameters to obtain the film thickness TH1 (nm). However, FIGS. 4A and 4B merely typically show a part of the basic data and an actual function may be different depending on the division zone. The basic data can be data previously acquired by an experiment, or the like. The system controller 123 can modify the basic data based on measurement results of the film-thickness measuring apparatus 100.

The basic data is not limited to the functions and can be, for example, a table indicating a relationship between the film thicknesses, and the gas flow rates and the heating temperatures. In the table, data on the film thicknesses and data on the gas flow rates and the heating temperatures corresponding to the film thicknesses is possibly discrete data at constant intervals. However, also in this case, when interpolation calculation of the film thickness, the gas flow rate, and the heating temperature not included in the data is performed by a linear interpolation method, or the like, the film forming parameters corresponding to arbitrary film thicknesses can be encompassed while the data size of the basic data is suppressed.

### (Process Flow)

At a first step (S1) of FIG. 5, the film forming part 11 performs a film formation of a first layer on the semiconductor substrate 2 mounted on the susceptor 112.

At this time, the system controller 123 reads the film-forming parameter data Da of FIG. 3A from the film-forming parameter storage part 14 and acquires the film-forming parameter values a1 of the first layer. The system controller 123 then outputs a control command signal corresponding to the acquired film-forming parameter values a1 of the first layer to the mass flow controllers 121 and the heater control parts 122. The mass flow controllers 121 thereby control the gas flow rates through the corresponding gas nozzles N to the gas flow rates indicated by the control command signal. The heater control parts 122 control the heating temperatures of the corresponding heaters H to the heating temperatures indicated by the control command signal.

After the film formation of the first layer is completed as described above, the system controller 123 controls the moving apparatus 1000 and causes the moving apparatus 100 to move the semiconductor substrate 2 on which the film formation of the first layer is completed, from the film forming part 11 to the film-thickness measuring apparatus 100.

Subsequently, at a second step (S2), the film-thickness measuring apparatus 100 performs a film thickness measurement of the first layer to the semiconductor substrate 2 which has been moved from the moving apparatus 1000 and on which the film formation of the first layer is completed. This film thickness measurement is controlled by the system controller 123. The film-thickness measuring apparatus 100 measures the film thickness of the first layer over all the division zones and notifies the system controller 123 of measurement results. The system controller 123 previously has a correspondence relationship between the position and the direction of the semiconductor substrate 2 on the susceptor 112 and the position and the direction of the semiconductor substrate 2 on the film-thickness measuring apparatus 100, for example, by coordinate data or the like. Accordingly, the system controller 123 can recognize to which division zone the measurement results of the film-thickness measuring apparatus 100 correspond.

After the notification of the measurement results by the film-thickness measuring apparatus 100, the system controller 123 registers the notified measurement results as the film-thickness measurement values b1 of the first layer in the film-thickness measurement result data Db of FIG. 3B.

Subsequently, at a third step (S3), the system controller 123 performs automatic selection of the film forming parameters of the second layer.

Specifically, the system controller 123 first acquires the next-layer film-thickness target values c1 of the first layer in the next-layer film-thickness target value data Dc of FIG. 3C. The next-layer film-thickness target values c1 of the first layer are target values for flattening, that is, horizontalizing the top surface of a film of the second layer.

The system controller 123 can acquire the next-layer film-thickness target values c1 of the first layer of FIG. 3C as input data of an input device (not shown) or acquire the values c1 through automatic calculation of the system controller 123.

When the next-layer film-thickness target values c1 of the first layer of FIG. 3C are acquired based on the input data, the system controller 123 can display an input screen of the target values c1 on a display and wait for progress of the film forming process until input of the target values c1 to the input screen is determined.

Meanwhile, when the configuration in which the next-layer film-thickness target values c1 of the first layer of FIG. 3C are acquired by the automatic calculation is adopted, it suffices to previously store second-layer height data in which the height of the top surface of a film of the second layer is set in the film-forming parameter storage part 14. The second-layer height data can be either fixed data or data that can be varied by the input device. The system controller 123 can read the second-layer height data from the film-forming parameter storage part 14 and calculate a difference between the height of the top surface of the film of the second layer and the film-thickness measurement values b1 of the first layer of FIG. 3B as the next-layer film-thickness target values c1 of the first layer of FIG. 3C. When the next-layer film-thickness target values of all layers of the next-layer film-thickness target value data Dc of FIG. 3C are to be acquired by the above automatic calculation, it suffices to previously store height data in which the height of the top surface of a film is set in the film-forming parameter storage part 14 also with respect to films of the third and succeeding layers.

The next-layer film-thickness target values c1 of the first layer of FIG. 3C acquired as described above are equivalent to values obtained by subtracting the film thickness of the first layer having an in-plane inclination from the target height of the top surface of a flat film of the second layer, and therefore indicate an in-plane inclination inverted with respect to the in-plane inclination of the first layer.

After the next-layer film-thickness target values c1 of the first layer of FIG. 3C are acquired, the system controller 123 reads the basic data from the basic database 13 and refers to the read basic data, thereby determining the film forming parameters (the gas flow rate and the heating temperature) to obtain the target values c1. The system controller 123 then registers the determined film forming parameters in the film-forming parameter data Da of FIG. 3A as the film-forming parameter values a2 of the second layer of FIG. 3A.

Around the third step (S3), the moving apparatus 1000 returns the semiconductor substrate 2 on which the film thickness measurement (S2) of the first layer is completed, from the film-thickness measuring apparatus 100 onto the susceptor 112. At this time, the moving apparatus 1000 matches the position and the direction of the semiconductor substrate 2 on the susceptor 112 with the position and the direction at the time of performing the film formation of the first layer.

Subsequently, at a fourth step (S4), the film forming part 11 performs film formation of the second layer using the film-forming parameter values a2 of the second layer of FIG. 3A to the semiconductor substrate 2 that has been returned onto the susceptor 112.

At this time, the system controller 123 reads the film-forming parameter data Da of FIG. 3A and acquires the film-forming parameter values a2 of the second layer of FIG. 3A registered at the third step (S3). The system controller 123 then outputs the control command signal corresponding to the acquired film-forming parameter values a2 of the second layer of FIG. 3A to the mass flow controllers 121 and the heater control parts 122.

The mass flow controllers 121 thereby control the gas flow rates of the nozzles N, respectively, to form the second layer in which the in-plane inclination is inverted with respect to that of the first layer. The heater control parts 122 control the heating temperatures of the heaters H, respectively, to form the second layer in which the in-plane inclination is inverted with respect to that of the first layer. As a result, the second layer is formed in which the in-plane inclination is inverted with respect to that of the first layer.

If the in-plane inclination of the second layer is the same as that of the first layer, the top surface of the second layer becomes less flat than that of the first layer. However, in the present embodiment, the in-plane inclination of the second layer can be inverted with respect to that of the first layer and therefore the top surface of the second layer can be flattened more than that of the first layer.

After the fourth step (S4), a fifth step (S5) and a sixth step (S6) are performed in sequence. At the fifth step (S5), the film-thickness measuring apparatus 100 performs a film thickness measurement to the second layer and registers the measurement results as the film-thickness measurement values b2 of the second layer in the film-thickness measurement result data Db of FIG. 3B. At the sixth step (S6), the system controller 123 acquires the next-layer film-thickness target values c2 of the second layer of FIG. 3C using the film-thickness measurement values b2 of the second layer of FIG. 3B and performs automatic selection of the film forming parameters of the third layer using the target values c2 and the basic data. The system controller 123 then registers the selected film forming parameters of the third layer as the film-forming parameter values a3 of the third layer in the film-forming parameter data Da of FIG. 3A. Steps of the film formation, the film thickness measurement, and the automatic selection of the film forming parameters are then repeated until a film formation of the uppermost layer, that is, a film formation of the stacked film 20 is completed.

At the time when the formation of the stacked film 20 is completed once together with the film thickness measurement and the automatic selection of the film forming parameters as described above, the system controller 123 registers film-forming parameter values relating to all layers in the film-forming parameter data Da of FIG. 3A.

The film-forming parameter values of each layer of the film-forming parameter data Da of FIG. 3A are calculated so as to attain the next-layer film-thickness target values of the next-layer film-thickness target value data Dc of FIG. 3C according to a default or the film-thickness measurement values of the film-thickness measurement result data Db of FIG. 3B. Accordingly, when the film formation is performed using the film-forming parameter values of each layer of the film-forming parameter data Da of FIG. 3A as they are, the next-layer film-thickness target values of each layer of the next-layer film-thickness target value data Dc of FIG. 3C can be attained.

Accordingly, second and succeeding formations of the stacked film 20 can be performed based on the film-forming parameter values of each layer registered in the film-forming parameter data Da of FIG. 3A. The second and succeeding formations of the stacked film 20 based on the film-forming parameter data Da of FIG. 3A can be controlled by the system controller 123. This eliminates the need of the film thickness measurement and the calculation of the film forming parameters based on the film-thickness measurement results as in the first formation and therefore the stacked film 20 can be formed promptly. As a result, the stacked film formation suitable for mass production can be performed.

According to the present embodiment, even if it is difficult to secure in-plane uniformity in each layer (that is, uniformity of the individual film thickness), the top surface of each layer of the stacked film 20 can be flattened more than in the conventional technique by forming an upper layer film in which the in-plane inclination is inverted with respect to that of a lower layer film. Furthermore, the entire in-plane uniformity of the stacked film 20 can be secured.

The present embodiment can be applied also to a stacked gate electrode of a three-dimensional stacked memory. For example, the stacked gate electrode is formed by stacking silicon layers and silicon dioxide films alternately. The present embodiment can be applied to flatten the top surface of the stacked gate electrode. When the top surface of the stacked gate electrode is flat, memory holes that penetrate the stacked gate electrode can be easily formed.

Furthermore, the inversion of the in-plane inclination of an upper layer film with respect to the in-plane inclination of a lower layer film is not necessarily limited to be performed continuously and can be performed every plural layers. An inversion degree of the in-plane inclination of each layer can be adjusted in such a manner that the in-plane inclination of a plurality of lower layer films can be absorbed by the in-plane inclination of one upper layer film or that the in-plane inclination of one lower layer film can be absorbed by the in-plane inclination of a plurality of upper layer films.

The film-forming parameter data Da of FIG. 3A can be used not only by the semiconductor manufacturing apparatus 10 itself of the semiconductor manufacturing system 1 that has the film-forming parameter data registered therein but also by other semiconductor manufacturing apparatuses that perform a stacked film formation in the same film forming environment (for example, the model of the apparatuses or the structure of the stacked film) as that of the semiconductor manufacturing apparatus 10. In this case, the film-forming parameter data Da of FIG. 3A can be stored in a recording medium such as a flexible disk or a CD-ROM depending on the mode of the data itself or a mode of a stacked film-forming program created based on the data. The stacked film-forming program is a program for causing a computer to execute a procedure for reading the data Da from the recording medium in which the film-forming parameter data Da of FIG. 3A is recorded, and a procedure for repeating, until the film formation of all layers is completed, a control on the film forming part 11 to form a film of a corresponding layer according to the film-forming parameter values of the corresponding layer of the stacked film in the read data Da. The film-forming parameter data Da of FIG. 3A or the stacked film-forming program stored in the recording medium can be caused to be read by computers of other semiconductor manufacturing apparatuses and used in the stacked-film forming process. The recording medium is not limited to detachable devices such as a magnetic disk and an optical disk, and can be a fixed-type recording medium such as a hard disk device and a memory. Furthermore, the film-forming parameter data Da of FIG. 3A or the stacked film-forming program can be distributed via a communication line (including wireless communication) such as the Internet. Further, the film-forming parameter data Da or the stacked film-forming program can be also distributed via a wired communication line such as the Internet or a wireless communication line in a state where the program is encrypted, modulated, or compressed, or distributed as the program is stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a film forming part forming a stacked film on a semiconductor substrate, the stacked film having a lower layer and an upper layer on the lower layer; and
a control part controlling the film forming part, wherein
the control part controls the film forming part to form the upper layer film in which an inclination of a film thickness in a plane of the semiconductor substrate is inverted with respect to that of the lower layer film.

2. The apparatus of claim 1, wherein
the film forming part comprises:
a plurality of gas nozzles injecting a film forming gas toward positions different from each other of the semiconductor substrate; and
a plurality of heaters heating positions different from each other of the semiconductor substrate, and
the control part comprises:
a mass flow controller controlling flow rates of the film forming gas for the gas nozzles, respectively; and
a heater control part controlling temperatures of the heating for the heaters, respectively.

3. The apparatus of claim 1, wherein the control part calculates a film forming parameter of the upper layer film based on a film-thickness measurement result of the lower layer film and basic data indicating a correspondence relationship between film thicknesses and film forming parameters, and controls the film forming part to form the upper layer film according to the calculated film forming parameter.

4. The apparatus of claim 2, wherein the control part calculates a film forming parameter of the upper layer film based on a film-thickness measurement result of the lower layer film and basic data indicating a correspondence relationship between film thicknesses and film forming parameters, and controls the film forming part to form the upper layer film according to the calculated film forming parameter.

5. The apparatus of claim 3, wherein the control part calculates the film forming parameter of the upper layer film further based on a film-thickness target value of the upper layer film for flattening a top surface of the upper layer film.

6. The apparatus of claim 4, wherein the control part calculates the film forming parameter of the upper layer film further based on a film-thickness target value of the upper layer film for flattening a top surface of the upper layer film.

7. The apparatus of claim 1, further comprising a storage part having respective film forming parameters of layers of the stacked film stored therein, wherein
the control part controls the film forming part so as to form the upper layer film according to the film forming parameter of the upper layer film acquired from the storage part.

8. The apparatus of claim 2, further comprising a storage part having respective film forming parameters of layers of the stacked film stored therein, wherein
the control part controls the film forming part so as to form the upper layer film according to the film forming parameter of the upper layer film acquired from the storage part.

9. A semiconductor manufacturing system comprising:
a semiconductor manufacturing apparatus comprising a film forming part forming a stacked film on a semiconductor substrate and a control part controlling the film forming part;
a film-thickness measuring apparatus; and
a database of basic data indicating a correspondence relationship between film thicknesses and film forming parameters, wherein
the control part calculates a film forming parameter of an upper layer film based on a film-thickness measurement result of a lower layer film obtained by the film-thickness measuring apparatus and the basic data of the database, and controls the film forming part to form the upper layer film in which an inclination of a film thickness in a plane of the semiconductor substrate is inverted with respect to that of the lower layer film according to the calculated film forming parameter.

10. The system of claim 9, wherein
the film forming part comprises:
a plurality of gas nozzles injecting a film forming gas toward positions different from each other of the semiconductor substrate; and
a plurality of heaters heating positions different from each other of the semiconductor substrate, and
the control part comprises:
a mass flow controller controlling flow rates of the film forming gas for the gas nozzles, respectively; and
a heater control part controlling temperature of the heating for the heaters, respectively.

11. The system of claim 9, wherein the control part calculates the film forming parameter of the upper layer film further based on a film-thickness target value of the upper layer film for flattening a top surface of the upper layer film.

12. The system of claim 10, wherein the control part calculates the film forming parameter of the upper layer film further based on a film-thickness target value of the upper layer film for flattening a top surface of the upper layer film.

13. A semiconductor manufacturing method comprising:
forming, on a semiconductor substrate, a stacked film including an upper layer film in which an inclination of a film thickness in a plane of the semiconductor substrate is inverted with respect to that of a lower layer film, wherein
the forming of the stacked film comprises:
forming the lower layer film on the semiconductor substrate;
performing a film thickness measurement of the lower layer film;
acquiring basic data indicating a correspondence relationship between film thicknesses and film forming parameters from a database of the basic data;
calculating a film forming parameter of the upper layer film based on the acquired basic data and a result of the film-thickness measurement of the lower layer film; and
forming the upper layer film according to the calculated film forming parameter of the upper layer film.

14. The method of claim 13, wherein the film forming parameter of the upper layer film is calculated based on a film-thickness target value of the upper layer film for flattening a top surface of the upper layer film.

15. The method of claim 13, wherein
the calculated film forming parameter of the upper layer film is stored in a storage part, and
forming of the upper layer film of next and succeeding times is performed according to the film forming parameter stored in the storage part.

16. The method of claim 14, wherein
the calculated film forming parameter of the upper layer film is stored in a storage part, and
forming of the upper layer film of next and succeeding times is performed according to the film forming parameter stored in the storage part.
